(19) United States
(12) Patent Application Publication
(10) Pub. No.: US 2018/0257556 A1
(43) Pub. Date: Sep. 13, 2018

(54) GROUNDED REFLECTOR FOR A VEHICLE LIGHTING FIXTURE WITH A CAPACITIVE SWITCH

(71) Applicant: Ford Global Technologies, LLC, Dearborn, MI (US)

(72) Inventors: Stuart C. Salter, White Lake, MI (US); Paul Kenneth Dellock, Northville, MI (US); Pietro Buttolo, Dearborn Heights, MI (US); Michael A. Musleh, Canton, MI (US); Talat Karmo, Waterford, MI (US)

(21) Appl. No.: 15/456,432

(22) Filed: Mar. 10, 2017

(51) Int. Cl. B60Q 3/60; H03K 17/96; B60Q 3/82

(52) U.S. Cl. CPC B60Q 3/60; B60Q 3/82; H03K 17/962

(57) ABSTRACT

Apparatus are disclosed for a grounded reflector for a vehicle lighting fixture with a capacitive switch. An example disclosed lamp assembly for a vehicle includes a lamp assembly, a grounded reflector, and a capacitive switch. The grounded reflector has a metal layer electrically coupled to a ground plane of the vehicle. However, the metal layer is not directly coupled to the ground plane of the vehicle. The capacitive switch is electrically coupled to the lamp assembly to control the lamp assembly based on detecting a capacitive object within a detection field.

### TECHNICAL FIELD

The present disclosure generally relates to lighting fixtures for vehicles and, more specifically, a grounded reflector for a vehicle lighting fixture with a capacitive switch.

### BACKGROUND

Increasingly, vehicles manufacturers are transitioning from physical buttons to touch screens and capacitive switches. Metal near these interfaces can cause parasitic capacitance that interferes with the ability of these interfaces to detect input unless that metal is grounded. Often, vehicle manufactures design parts to remove metal near these interfaces. However, this can compromise aesthetics and utility of other parts of the vehicles, such as a reflector for a vehicle lighting fixture.

### SUMMARY

The appended claims define this application. The present disclosure summarizes aspects of the embodiments and should not be used to limit the claims. Other implementations are contemplated in accordance with the techniques described herein, as will be apparent to one having ordinary skill in the art upon examination of the following drawings and detailed description, and these implementations are intended to be within the scope of this application.

Example embodiments are disclosed for a grounded reflector for a vehicle lighting fixture with a capacitive switch. An example disclosed lamp assembly for a vehicle includes a lamp assembly, a grounded reflector, and a capacitive switch. The grounded reflector has a metal layer electrically coupled to a ground plane of the vehicle. However, the metal layer is not directly coupled to the ground plane of the vehicle. The capacitive switch is electrically coupled to the lamp assembly to control the lamp assembly based on detecting a capacitive object within a detection field.

An example disclosed reflector for a vehicle light fixture includes a conductive thermoplastic layer, a metal layer, and grounding pins. The metal layer covers a concave surface of the thermoplastic layer. The grounding pins are embedded in the conductive thermoplastic layer. Additionally, the grounding pins are not in direct contact with the metal layer.

### BRIEF DESCRIPTION OF THE DRAWINGS

For a better understanding of the invention, reference may be made to embodiments shown in the following drawings. The components in the drawings are not necessarily to scale and related elements may be omitted, or in some instances proportions may have been exaggerated, so as to emphasize and clearly illustrate the novel features described herein. In addition, system components can be variously arranged, as known in the art. Further, in the drawings, like reference numerals designate corresponding parts throughout the several views.

FIG. 1 illustrates a vehicle with a lighting fixture that includes a capacitive switch in accordance with the teachings of this disclosure.

FIGS. 2A and 2B illustrate the lighting fixture of FIG. 1 with a grounded reflector.

FIG. 3 illustrates a cross-sectional view of the grounded reflector of FIGS. 2A and 2B.

### DETAILED DESCRIPTION OF EXAMPLE EMBODIMENTS

While the invention may be embodied in various forms, there are shown in the drawings, and will hereinafter be described, some exemplary and non-limiting embodiments, with the understanding that the present disclosure is to be considered an exemplification of the invention and is not intended to limit the invention to the specific embodiments illustrated.

Lighting fixtures (e.g., overhead console lights, dome lights, etc.) that include capacitive switches are activated by detecting a change in capacitance within a detection field of the capacitive switch caused by capacitive object, such as a human hand. For example, the lighting fixture may turn on and off when a person taps a lens of the lighting fixture or plastic around the lighting fixture. These light fixtures include a lens, a light source (e.g., one or more light emitting diodes (LEDs), etc.) and a reflector. The reflector includes a metal surface to increase the light produced by the lighting fixture. However, because the metal is close the capacitive switch (e.g., 10 to 15 millimeters (mm), etc.), the capacitive switch creates parasitic capacitance, hidden switches, and/or electromagnetic interference issues as the detection field radiates from the switch.

Traditionally, grounding the metal surface is attempted by (a) soldering a wire to the metal surface or using a crimp-on connector to attach the wire to the metal surface and then attaching the wire to ground, or (b) vacuum metalizing both sides of the reflector housing and creating a ground metal contact to the metallic surface. These methods are not robust because they can be complicated to install in production and can fail over time because the connections either break or increase in their resistance. Additionally, to ensure a long term low resistance connection, gold plating may be used. This further increases the cost.

As disclosed below, the reflector housing is molded out of a material that is electrically conductive. In some examples, the material (a) has a relatively low specific gravity to dissipate heat, (b) has a melting point above 210 degrees Celsius (C), is dimensionally stable, (d) have a relatively high service temperature range, (e) relatively low cost, (f) a thermoplastic material that can be precision molded into complex shapes, and (g) recyclable. Grounding wire(s) and/or pins are molded into the reflector housing and exposed on a convex portion of the reflector housing. When installed in a vehicle, the grounding wire(s) and/or pins are connected to ground. The reflector housing is metalized on a concave portion of the reflector housing. In some examples, a metal layer is applied to the concave portion of the reflector housing using a vacuum metallization process. The grounded reflector facilitates capacitive switches being package next to the metallic surface without parasitic capacitance, hidden switches, and/or electromagnetic interference issues. Additionally, molding the grounding wire(s) and/or pins molded into the conductive thermoplastic housing of the reflector facilitates an electrical and mechanical robust connection between the housing and the ground of the vehicle.

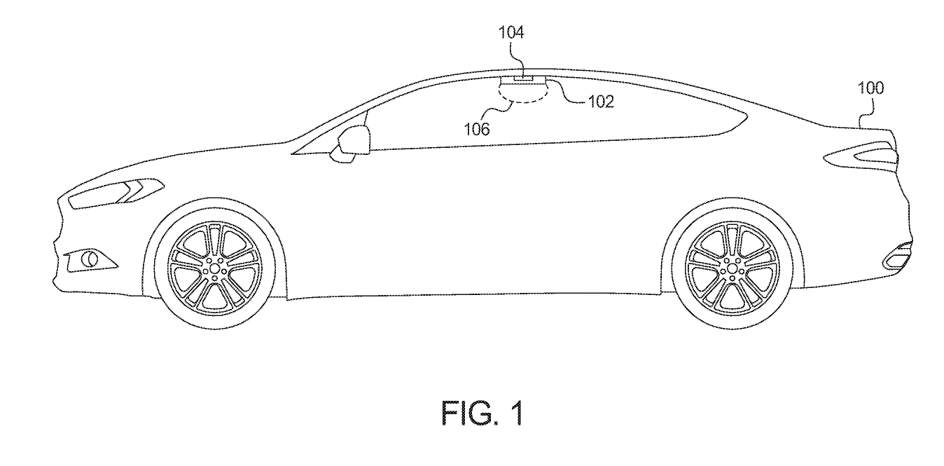

FIG. 1 illustrates a vehicle 100 with a lighting fixture 102 that includes a capacitive switch 104 in accordance with the teachings of this disclosure. The vehicle 100 may be a standard gasoline powered vehicle, a hybrid vehicle, an electric vehicle, a fuel cell vehicle, and/or any other mobility implement type of vehicle. The vehicle 100 includes parts related to mobility, such as a powertrain with an engine, a transmission, a suspension, a driveshaft, and/or wheels, etc. The vehicle 100 may be non-autonomous, semi-autonomous (e.g., some routine motive functions controlled by the vehicle 100), or autonomous (e.g., motive functions are controlled by the vehicle 100 without direct driver input).

While FIG. 1 illustrates the vehicle 100 with one lighting fixture 102, the vehicle 100 may include multiple light fixtures that operating in accordance with the teachings of this disclosure. For example, the lighting fixtures 102 may be overhead console lights, dome lights, and/or cargo lights, etc. The capacitive switch 104 of the lighting fixture 102 generates a detection field 106. A capacitive material within the detection field 106 causes the capacitance of the capacitive switch 104 to change. When the change in the capacitance of the capacitive switch 104 is greater than a threshold, the switch inverts (e.g., from off to on of from on to off). For example, the detection field 106 may be configured to detect a hand touching a plastic molding around the lighting fixture 102.

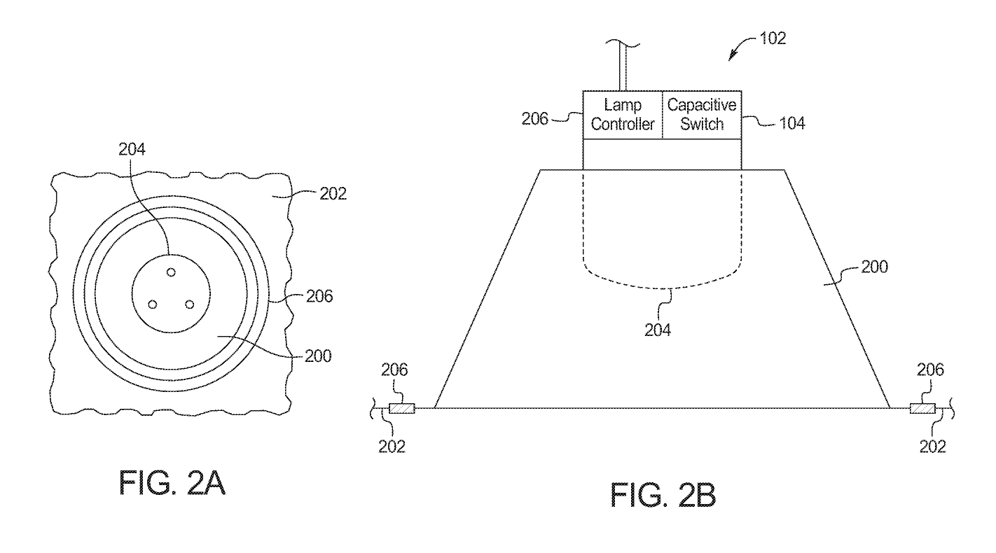

FIGS. 2A and 2B illustrate the lighting fixture 102 of FIG. 1 with a grounded reflector 200. In the illustrated example, the grounded reflector 200 is a conical shape. However, the grounded reflector 200 may be any suitable shape for the shape requirements of a particular lighting fixture 102. The example lighting fixture 102 is recessed into a surface 202 (e.g., a wall, a ceiling, a console, etc.) of the vehicle 100. The lighting fixture 102 includes the capacitive switch 104, the grounded reflector 200, a lighting unit 204, and a lamp controller 206. In some examples, the lighting fixture 102 includes a metalized bezel 208.

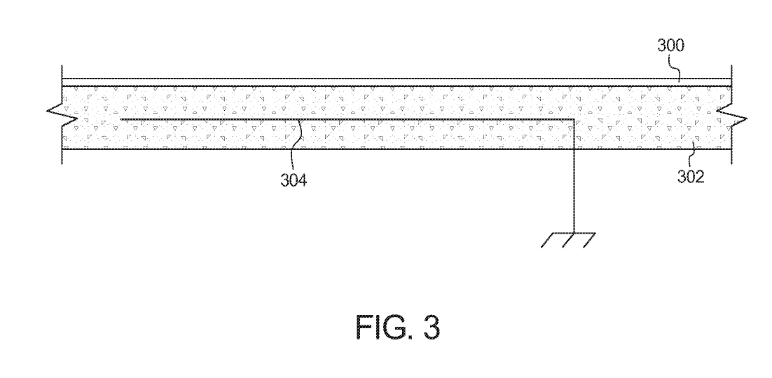

As described below in FIG. 3, the grounded reflector 200 is comprised of a conductive thermoplastic with a metalized surface. The grounded reflector 200 is electrically connected to the ground plane of the vehicle 100. The lighting unit 204 includes light emitting devices 210 (such as light emitting diodes (LEDs, etc.) and circuitry (not shown) to make the light emitting devices 210 operable. The lamp controller 206 is electrically coupled to (a) a power bus of the vehicle, (b) the capacitive switch 104, (c) and the lighting unit 204. The lamp controller 206 regulates power for the lighting unit 204. Additionally, the lamp controller 206 supplies power to the lighting unit 204 based on the condition of the capacitive switch 104.

FIG. 3 illustrates a cross-sectional view of the grounded reflector 200 of FIGS. 2A and 2B. In the illustrated example, the grounded reflector 200 includes a metal layer 300, a conductive thermoplastic layer 302, and one or more ground wires or pins 304 embedded in the conductive thermoplastic layer 302. The metal layer 300 is formed on the conductive thermoplastic layer 302 though a metallization process. In some example, the vacuum metalized onto the conductive thermoplastic layer 302. The metal layer 300 is not directly coupled to the ground plane of the vehicle. As used herein, “directly couple” means that there is some of the thermoplastic layer 302 between the metal layer 300 and the ground wires or pins 304 (e.g., the ground wires or pins 304 are not attached to the metal layer 300). In some examples, the metalized bezel 208 includes the metal layer 300, the conductive thermoplastic layer 302, and the ground wires or pins 304 embedded in the conductive thermoplastic layer 302.

The conductive thermoplastic layer 302 may be any thermoplastic material with a melting temperature of at least 210 degrees Celsius. In some examples, the conductive thermoplastic layer 302 is polyethylene terephthalate (PET). The conductive thermoplastic layer 302 is impregnated with graphite. In some examples, the graphite is a high aspect ratio graphite (such as TIMREX® C-THERM™ 001, etc.). In such example, the high aspect ratio graphite improves the electrical and thermal conductivity of the thermoplastic. For example, unmodified PET may have a volume resistivity of about 1016 ohm.cm and a thermal conductivity of about 0.22 W/mK. In such an example, the graphite-impregnated PET may have a volume resistivity of about 102 Ohm.cm and a thermal conductivity of about 3.4 W/mK.

The ground wires or pins 304 are embedded into the conductive thermoplastic layer 302 when the grounded reflector 200 is molded. In some examples, the ground wires and/or pins 304 are not in direct contact with the metal layer 300. When the ground wires or pins 304 are connected to the ground plane of the vehicle 100, the conductive thermoplastic layer 302 and the ground wires or pins 304 provide a conductive path between the metal layer 300 and the ground plane of the vehicle 100. In such a manner, the metal layer 300 is grounded to prevent parasitic capacitance, hidden switches, and/or electromagnetic interference issues.

In this application, the use of the disjunctive is intended to include the conjunctive. The use of definite or indefinite articles is not intended to indicate cardinality. In particular, a reference to “the” object or “a” and “an” object is intended to denote also one of a possible plurality of such objects. Further, the conjunction “or” may be used to convey features that are simultaneously present instead of mutually exclusive alternatives. In other words, the conjunction “or” should be understood to include “and/or”. The terms “includes,” “including,” and “include” are inclusive and have the same scope as “comprises,” “comprising,” and “comprise” respectively.

The above-described embodiments, and particularly any “preferred” embodiments, are possible examples of implementations and merely set forth for a clear understanding of the principles of the invention. Many variations and modifications may be made to the above-described embodiment(s) without substantially departing from the spirit and principles of the techniques described herein. All modifications are intended to be included herein within the scope of this disclosure and protected by the following claims.

1. A lighting fixture for a vehicle comprising:
a lamp assembly;
a grounded reflector including:
a conductive thermoplastic layer; and
a metal layer having the shape of the conductive thermoplastic layer electrically coupled to a ground plane of the vehicle via the conductive thermoplastic layer; and
a capacitive switch electrically coupled to the lamp assembly to control the lamp assembly by detecting a capacitive object within a detection field.

2. The lighting fixture of claim 1, wherein the grounded reflector includes a grounding wire embedded in the conductive thermoplastic layer.

3. The lighting fixture of claim 1, wherein the conductive thermoplastic layer is impregnated with high aspect ratio graphite.

4. The lighting fixture of claim 1, wherein the conductive thermoplastic layer has a melting point of at least 210 degrees Celsius.

5. The lighting fixture of claim 1, wherein the conductive thermoplastic layer is polyethylene terephthalate.

6. The lighting fixture of claim 1, wherein the grounding wire is connected to the ground plane of the vehicle.

7. The lighting fixture of claim 1, including a bezel with the metal layer.

8. The lighting fixture of claim 7, wherein the bezel includes:
a conductive thermoplastic layer impregnated with high aspect ratio graphite; and
a second grounding wire connected to the ground plane of the vehicle.

9. A reflector for a vehicle light fixture comprising:
a conductive thermoplastic layer;
a metal layer covering a rounded concave surface of the conductive thermoplastic layer, the metal layer having the same shape as the conductive thermoplastic layer; and
grounding pins embedded in the conductive thermoplastic layer, the grounding pins not in direct contact with the metal layer.

10. The reflector of claim 9, wherein the conductive thermoplastic layer is impregnated with high aspect ratio graphite.

11. The reflector of claim 9, wherein the conductive thermoplastic layer has a melting point of at least 210 degrees Celsius.

12. The reflector of claim 9, wherein the conductive thermoplastic layer is polyethylene terephthalate.

13. The reflector of claim 9, wherein the grounding pins are electrically coupled to a ground plane of a vehicle.

14. The lighting fixture of claim 1, wherein the grounded reflector is a truncated cone.

15. The lighting fixture of claim 14, wherein the metal layer forms an interior portion of the truncated cone and the conductive thermoplastic layer forms an exterior portion of the truncated cone.
